(19) United States
(12) Patent Application Publication
(10) Pub. No.: US 2006/0024451 A1
(43) Pub. Date: Feb. 2, 2006

(54) Enhanced magnetic shielding for plasma-based semiconductor processing tool

(75) Inventors: Hemant P. Mungkekar, San Jose, CA (US); Muhammad M. Rasheed, Fremont, CA (US); Narendra Dubey, San Jose, CA (US)

Correspondence Address: Patent Counsel;Applied Materials, Inc., Legal Affairs Department, P.O. Box 450A, M/S 2061, Santa Clara, CA, 95052, US

(73) Assignees: Applied Materials Inc., Santa Clara, CA (US); A Delaware Corporation

(21) Appl. No.: 10/989,885

(22) Filed: Nov. 16, 2004

Related U.S. Application Data
(60) Provisional application No. 60/592,417, filed on Jul. 30, 2004.

(51) Int. Cl. H05H 1/24; C23C 16/00

(52) U.S. Cl. 427/569; 118/719

(57) ABSTRACT

Embodiments in accordance with the present invention relate to techniques for enhancing uniformity of plasma-based semiconductor processing. In one technique, the exterior of a plasma-based processing chamber features a series of substantially continuous plates composed of a material exhibiting a low permeability to magnetic fields. This high-μ shielding material is utilized to block exposure of a plasma within the chamber to the effects of external magnetic fields. Embodiments in accordance with the present invention are effective to shield plasma-based processing chambers from external magnetic fields originating from adjacent clustered chambers, and/or from the earth's geomagnetic field.

### CROSS-REFERENCES TO RELATED APPLICATIONS

The instant U.S. nonprovisional patent application claims priority to U.S. provisional application No. 60/592,417, filed Jul. 30, 2004, which is incorporated by reference herein for all purposes

### BACKGROUND OF THE INVENTION

The present invention relates to the manufacture of integrated circuits on a substrate. More particularly, the invention relates to a method and apparatus for improving the process uniformity of plasma processing techniques used in such manufacture.

One of the primary steps in the fabrication of modern semiconductor devices is the formation of a thin film on a semiconductor substrate by chemical reaction of gases. Such a deposition process is referred to generally as chemical vapor deposition (“CVD”). Conventional thermal CVD processes supply reactive gases to the substrate surface where heat-induced chemical reactions take place to produce a desired film. Plasma-enhanced CVD (“PECVD”) techniques, on the other hand, promote excitation and/or dissociation of the reactant gases by the application of radio-frequency (“RF”) energy to a reaction zone near the substrate surface, thereby creating a plasma. The high reactivity of the species in the plasma reduces the energy required for a chemical reaction to take place, and thus lowers the temperature required for such CVD processes as compared to conventional thermal CVD processes. These advantages are further exploited by high-density-plasma (“HDP”) CVD techniques, in which a dense plasma is formed at low vacuum pressures so that the plasma species are even more reactive.

Any of these CVD techniques may be used to deposit conductive or insulative films as necessary during the fabrication of integrated circuits. It is generally desirable that the process for depositing such a film be uniform in all respects. Recently, there has been an economically motivated trend to increase the size of circular semiconductor wafers used in such CVD applications. Currently, wafers with diameters up to 300 mm are being used, up from about 200 mm in the recent past. While the increase in wafer diameter is economically advantageous, it also tends to increase the degree of nonuniformity introduced during deposition procedures. The effects of such nonuniformity are especially noticeable when larger wafers are used because the total wafer area varies as the square of its diameter. In particular, it has been observed that the sputter nonuniformity in an HDP-CVD process is significantly greater when the process is performed on a 300-mm wafer when compared with the process performed on a 200-mm wafer. Indications suggest that if economic considerations push towards the use of even larger wafers, the effects of sputter nonuniformity will be even greater.

Accordingly, it is desirable to have a method and apparatus that will generally improve process uniformity, particularly when larger-sized wafers are to be used.

### SUMMARY OF THE INVENTION

Embodiments in accordance with the present invention relate to techniques for enhancing uniformity of plasma-based semiconductor processing. In one technique, the exterior of a plasma-based processing chamber features a series of substantially continuous plates composed of a material exhibiting a low permeability to magnetic fields. This high-μ shielding material is utilized to block exposure of a plasma within the chamber to the effects of external magnetic fields. Embodiments in accordance with the present invention are effective to shield plasma-based processing chambers from external magnetic fields originating from adjacent clustered chambers, and/or from the earth's geomagnetic field.

An embodiment of a method in accordance with the present invention for forming a material by plasma-assisted chemical vapor deposition, comprising, disposing a reactant gas in a first plasma processing chamber of a cluster tool, the first plasma processing chamber featuring a first electromagnetic shield. The reactant gas is disposed in a second plasma processing chamber of the cluster tool, the second plasma processing chamber featuring a second electromagnetic shield. High density plasma is introduced into the first and second plasma processing chambers to cause reaction between reactants and deposit material therein. The first and second electromagnetic shields insulate the first and second plasma processing chambers from external electromagnetic fields, such that an axisymmetry index of a film deposited in the first chamber differs from an axisymmetry index of a film deposited in the second chamber by about 80 Å or less.

An embodiment of a method in accordance with the present invention for quantifying uniformity of a material deposited on a substantially circular substrate, comprises, sampling a property of the material at a plurality of pairs of diametrically opposed positions on a circumference of a sampling circle having a center coincident with a center of the substrate. A plurality of differences between the property sampled at each of the diametrically opposed position pairs is determined. The absolute value of each of the plurality of the differences is taken. The absolute values are averaged to calculate an axisymmetry index having a unit that is the same as the sampled property.

An embodiment of a method in accordance with the present invention for forming a material by high density plasma chemical vapor deposition (HDP-CVD), comprises, disposing a reactant gas in a plasma processing chamber equipped with an electromagnetic shield, and introducing high density plasma into the plasma processing chamber to cause reaction between reactants and deposit material therein, wherein a presence of the electromagnetic shield improves a uniformity of the material as deposited, prior to concurrent HDP-CVD sputtering.

An embodiment of a semiconductor processing cluster tool in accordance with the present invention, comprises, a first plasma processing chamber equipped with a first electromagnetic shield and configured to receive a process gas, and a second plasma processing chamber equipped with a second electromagnetic field and configured to receive the process gas. The first and second electromagnetic shields insulate the first and second plasma processing chambers from external electromagnetic fields, such that an axisymmetry index of the material deposited in the first chamber differs from an axisymmetry index of the material deposited in the second chamber by about 80 Å or less.

A further understanding of embodiments in accordance with the present invention can be made by way of reference to the ensuing detailed description taken in conjunction with the accompanying drawings.

### BRIEF DESCRIPTION OF THE DRAWINGS

FIG. 1A is a simplified diagram of one embodiment of a high-density plasma chemical vapor deposition system according to the present invention.

FIG. 1B is a simplified cross section of a gas ring that may be used in conjunction with the exemplary CVD processing chamber of FIG. 1A.

FIG. 1C is a simplified diagram of a monitor and light pen that may be used in conjunction with the exemplary CVD processing chamber of FIG. 1A.

FIG. 1D is a flow chart of an exemplary process control computer program product used to control the exemplary CVD processing chamber of FIG. 1A;

FIG. 2 shows a cross-sectional view of one embodiment of the invention in which the magnetic flux leakage of a high-permeability magnetic shield is minimized.

FIGS. 3A-C show different simplified perspective views of a conventional HDP-CVD chamber.

FIG. 3D shows a contour map of a wafer bearing a layer deposited in the conventional chamber of FIGS. 3A-C.

FIG. 4A shows a simplified perspective view of an embodiment of a shielded HDP-CVD chamber.

FIG. 4B shows a contour map of a wafer bearing a layer deposited in the chamber of FIG. 4A.

FIGS. 5A-C shows a simplified perspective view of another embodiment of a shielded HDP-CVD chamber.

FIG. 5D shows a contour map of a wafer bearing a layer deposited in the chamber of FIGS. 5A-C.

FIG. 6 shows a simplified schematic plan view of a pair of cluster tools featuring multiple plasma-based processing chambers.

FIG. 7 shows a simplified schematic diagram defining an axi-symmetry index.

FIG. 8A plots axi-symmetry index for wafer bearing layers deposited in certain of the unshielded chambers of a pair of conventional cluster tools of the type shown in FIG. 6.

FIG. 8B plots axi-symmetry index for wafers bearing layers deposited in certain shielded chambers of a pair of cluster tools of the type shown in FIG. 6.

FIG. 9A is a schematic diagram correlating the axi-symmetry index data of FIG. 8A with orientation of clustered plasma-based processing chambers relative to the earth's magnetic field.

FIG. 9B is a schematic diagram correlating change in axi-symmetry index data of FIGS. 8A-B, with orientation of clustered plasma-based processing chambers relative to the earth's magnetic field.

### DESCRIPTION OF THE SPECIFIC EMBODIMENTS

### I. Introduction

Embodiments of the present invention are directed to a method and apparatus for improving the process uniformity during plasma CVD deposition processes. By enclosing the plasma chamber with a substantially continuous shield constructed from a high-magnetic-permeability material, a substantial improvement in process uniformity, particularly in sputter uniformity, is achieved. As explained in detail below, attenuation of magnetic fields on the order of 0.5 gauss or less within the process chamber reduces the sputter nonuniformity, leading to a general improvement in deposition characteristics.

### II. Exemplary Substrate Processing System

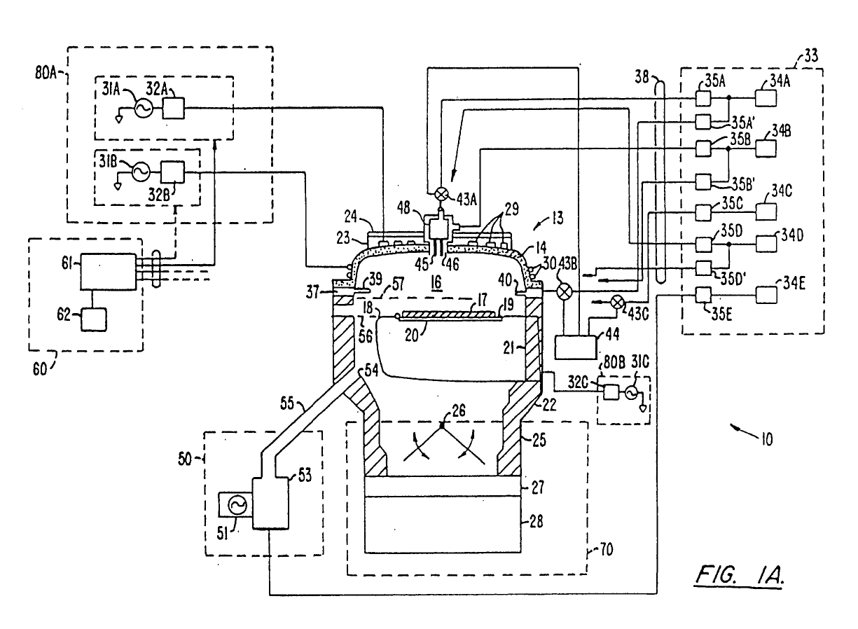

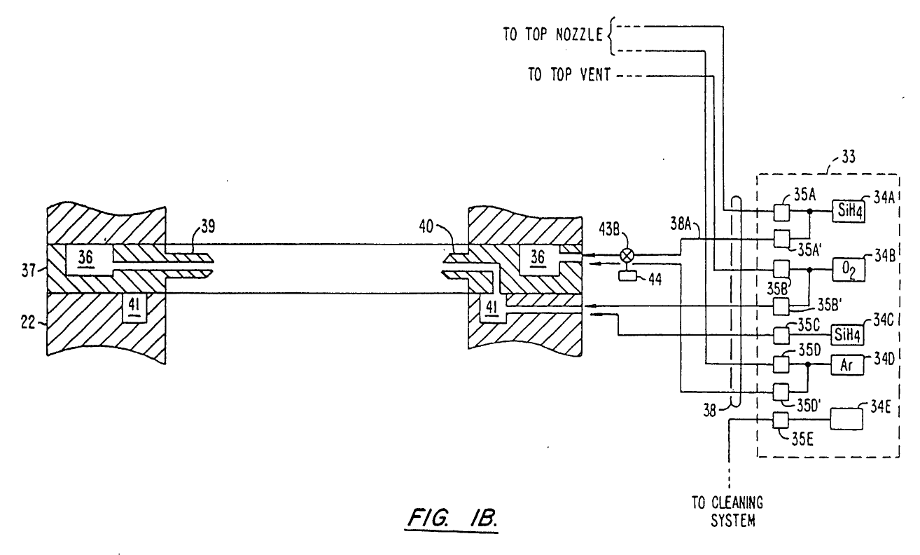

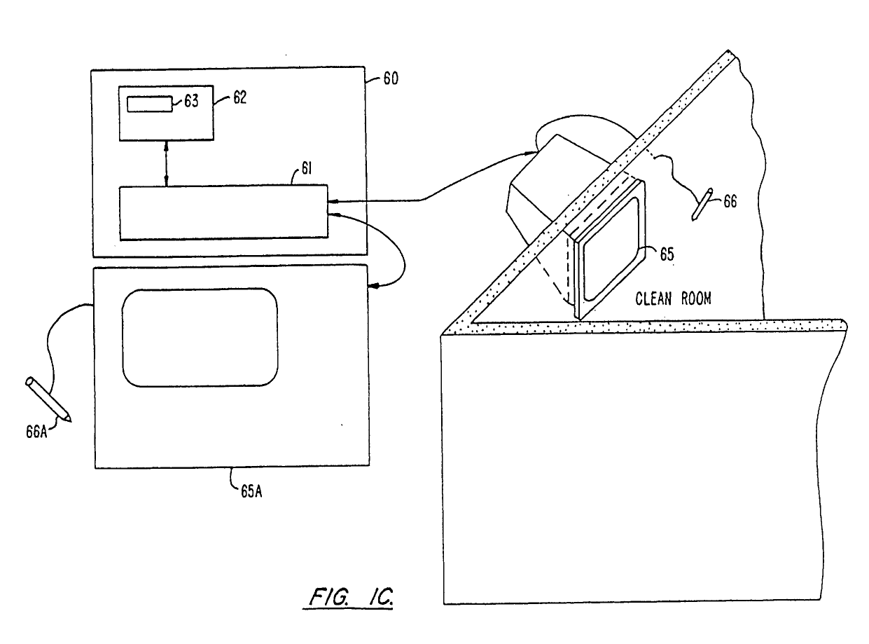

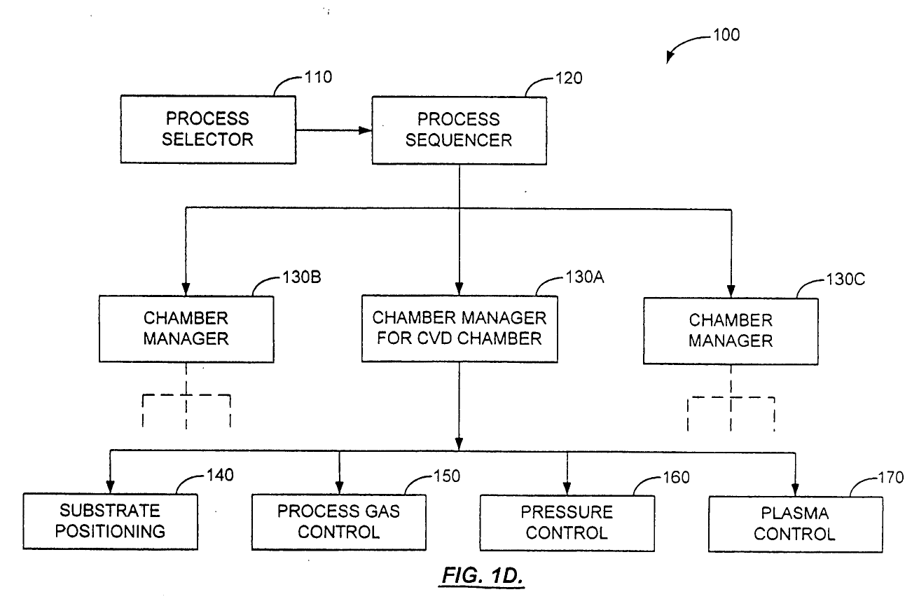

FIG. 1A illustrates one embodiment of a high density plasma chemical vapor deposition (HDP-CVD) system 10 in which a dielectric layer according to the present invention can be deposited. System 10 includes a chamber 13, a vacuum system 70, a source plasma system 80A, a bias plasma system 80B, a gas delivery system 33, and a remote plasma cleaning system 50.

The upper portion of chamber 13 includes a dome 14, which is made of a ceramic dielectric material, such as aluminum oxide or aluminum nitride. Dome 14 defines an upper boundary of a plasma processing region 16. Plasma processing region 16 is bounded on the bottom by the upper surface of a substrate 17 and a substrate support member 18.

A heater plate 23 and a cold plate 24 surmount, and are thermally coupled to, dome 14. Heater plate 23 and cold plate 24 allow control of the dome temperature to within about ±10° C. over a range of about 100° C. to 200° C. This allows optimizing the dome temperature for the various processes. For example, it may be desirable to maintain the dome at a higher temperature for cleaning or etching processes than for deposition processes. Accurate control of the dome temperature also reduces the flake or particle counts in the chamber and improves adhesion between the deposited layer and the substrate.

The lower portion of chamber 13 includes a body member 22, which joins the chamber to the vacuum system. A base portion 21 of substrate support member 18 is mounted on, and forms a continuous inner surface with, body member 22. Substrates are transferred into and out of chamber 13 by a robot blade (not shown) through an insertion/removal opening (not shown) in the side of chamber 13. Lift pins (not shown) are raised and then lowered under the control of a motor (also not shown) to move the substrate from the robot blade at an upper loading position 57 to a lower processing position 56 in which the substrate is placed on a substrate receiving portion 19 of substrate support member 18. Substrate receiving portion 19 includes an electrostatic chuck 20 that secures the substrate to substrate support member 18 during substrate processing. In a preferred embodiment, substrate support member 18 is made from an aluminum oxide or aluminum ceramic material.

Vacuum system 70 includes throttle body 25, which houses twin-blade throttle valve 26 and is attached to gate valve 27 and turbo-molecular pump 28. It should be noted that throttle body 25 offers minimum obstruction to gas flow, and allows symmetric pumping. Gate valve 27 can isolate pump 28 from throttle body 25, and can also control chamber pressure by restricting the exhaust flow capacity when throttle valve 26 is fully open. The arrangement of the throttle valve, gate valve, and turbo-molecular pump allow accurate and stable control of chamber pressures from between about 1 millitorr to about 2 torr.

The source plasma system 80A includes a top coil 29 and side coil 30, mounted on dome 14. A symmetrical ground shield (not shown) reduces electrical coupling between the coils. Top coil 29 is powered by top source RF (SRF) generator 31A, whereas side coil 30 is powered by side SRF generator 31B, allowing independent power levels and frequencies of operation for each coil. This dual coil system allows control of the radial ion density in chamber 13, thereby improving plasma uniformity. Side coil 30 and top coil 29 are typically inductively driven, which does not require a complimentary electrode. In a specific embodiment, the top source RF generator 31A provides up to 2,500 watts of RF power at nominally 2 MHz and the side source RF generator 31B provides up to 5,000 watts of RF power at nominally 2 MHz. The operating frequencies of the top and side RF generators may be offset from the nominal operating frequency (e.g. to 1.7-1.9 MHz and 1.9-2.1 MHz, respectively) to improve plasma-generation efficiency.

A bias plasma system 80B includes a bias RF (“BRF”) generator 31C and a bias matching network 32C. The bias plasma system 80B capacitively couples substrate portion 17 to body member 22, which act as complimentary electrodes. The bias plasma system 80B serves to enhance the transport of plasma species (e.g., ions) created by the source plasma system 80A to the surface of the substrate. In a specific embodiment, bias RF generator provides up to 5,000 watts of RF power at 13.56 MHz.

RF generators 31A and 31B include digitally controlled synthesizers and operate over a frequency range between about 1.8 to about 2.1 MHz. Each generator includes an RF control circuit (not shown) that measures reflected power from the chamber and coil back to the generator and adjusts the frequency of operation to obtain the lowest reflected power, as understood by a person of ordinary skill in the art. RF generators are typically designed to operate into a load with a characteristic impedance of 50 ohms. RF power may be reflected from loads that have a different characteristic impedance than the generator. This can reduce power transferred to the load. Additionally, power reflected from the load back to the generator may overload and damage the generator. Because the impedance of a plasma may range from less than 5 ohms to over 900 ohms, depending on the plasma ion density, among other factors, and because reflected power may be a function of frequency, adjusting the generator frequency according to the reflected power increases the power transferred from the RF generator to the plasma and protects the generator. Another way to reduce reflected power and improve efficiency is with a matching network.

Matching networks 32A and 32B match the output impedance of generators 31A and 31B with their respective coils 29 and 30. The RF control circuit may tune both matching networks by changing the value of capacitors within the matching networks to match the generator to the load as the load changes. The RF control circuit may tune a matching network when the power reflected from the load back to the generator exceeds a certain limit. One way to provide a constant match, and effectively disable the RF control circuit from tuning the matching network, is to set the reflected power limit above any expected value of reflected power. This may help stabilize a plasma under some conditions by holding the matching network constant at its most recent condition.

Other measures may also help stabilize a plasma. For example, the RF control circuit can be used to determine the power delivered to the load (plasma) and may increase or decrease the generator output power to keep the delivered power substantially constant during deposition of a layer.

A gas delivery system 33 provides gases from several sources, 34A-34F chamber for processing the substrate via gas delivery lines 38 (only some of which are shown). As would be understood by a person of skill in the art, the actual sources used for sources 34A-34F and the actual connection of delivery lines 38 to chamber 13 varies depending on the deposition and cleaning processes executed within chamber 13. Gases are introduced into chamber 13 through a gas ring 37 and/or a top nozzle 45. FIG. 1B is a simplified, partial cross-sectional view of chamber 13 showing additional details of gas ring 37.

In one embodiment, first and second gas sources, 34A and 34B, and first and second gas flow controllers, 35A′ and 35B′, provide gas to ring plenum 36 in gas ring 37 via gas delivery lines 38 (only some of which are shown). Gas ring 37 has a plurality of source gas nozzles 39 (only one of which is shown for purposes of illustration) that provide a uniform flow of gas over the substrate. Nozzle length and nozzle angle may be changed to allow tailoring of the uniformity profile and gas utilization efficiency for a particular process within an individual chamber. In a preferred embodiment, gas ring 37 has 12 source gas nozzles made from an aluminum oxide ceramic.

Gas ring 37 also has a plurality of oxidizer gas nozzles 40 (only one of which is shown), which in a preferred embodiment are co-planar with and shorter than source gas nozzles 39, and in one embodiment receive gas from body plenum 41. In some embodiments it is desirable not to mix source gases and oxidizer gases before injecting the gases into chamber 13. In other embodiments, oxidizer gas and source gas may be mixed prior to injecting the gases into chamber 13 by providing apertures (not shown) between body plenum 41 and gas ring plenum 36. In one embodiment, third and fourth gas sources, 34C and 34D, and third and fourth gas flow controllers, 35C and 35D′, provide gas to body plenum via gas delivery lines 38. Additional valves, such as 43B (other valves not shown), may shut off gas from the flow controllers to the chamber.

In embodiments where flammable, toxic, or corrosive gases are used, it may be desirable to eliminate gas remaining in the gas delivery lines after a deposition. This may be accomplished using a 3-way valve, such as valve 43B, to isolate chamber 13 from delivery line 38A and to vent delivery line 38A to vacuum foreline 44, for example. As shown in FIG. 1A, other similar valves, such as 43A and 43C, may be incorporated on other gas delivery lines. Such 3-way valves may be placed as close to chamber 13 as practical, to minimize the volume of the unvented gas delivery line (between the 3-way valve and the chamber). Additionally, two-way (on-off) valves (not shown) may be placed between a mass flow controller (“MFC”) and the chamber or between a gas source and an MFC.

Referring again to FIG. 1A, chamber 13 also has top nozzle 45 and top vent 46. Top nozzle 45 and top vent 46 allow independent control of top and side flows of the gases, which improves film uniformity and allows fine adjustment of the film's deposition and doping parameters. Top vent 46 is an annular opening around top nozzle 45. In one embodiment, first gas source 34A supplies source gas nozzles 39 and top nozzle 45. Source nozzle MFC 35A′ controls the amount of gas delivered to source gas nozzles 39 and top nozzle MFC 35A controls the amount of gas delivered to top gas nozzle 45. Similarly, two MFCs 35B and 35B′ may be used to control the flow of oxygen to both top vent 46 and oxidizer gas nozzles 40 from a single source of oxygen, such as source 34B. The gases supplied to top nozzle 45 and top vent 46 may be kept separate prior to flowing the gases into chamber 13, or the gases may be mixed in top plenum 48 before they flow into chamber 13. Separate sources of the same gas may be used to supply various portions of the chamber.

A remote microwave-generated plasma cleaning system 50 is provided to periodically clean deposition residues from chamber components. The cleaning system includes a remote microwave generator 51 that creates a plasma from a cleaning gas source 34E (e.g., molecular fluorine, nitrogen trifluoride, other fluorocarbons or equivalents) in reactor cavity 53. The reactive species resulting from this plasma are conveyed to chamber 13 through cleaning gas feed port 54 via applicator tube 55. The materials used to contain the cleaning plasma (e.g., cavity 53 and applicator tube 55) must be resistant to attack by the plasma. The distance between reactor cavity 53 and feed port 54 should be kept as short as practical, since the concentration of desirable plasma species may decline with distance from reactor cavity 53. Generating the cleaning plasma in a remote cavity allows the use of an efficient microwave generator and does not subject chamber components to the temperature, radiation, or bombardment of the glow discharge that may be present in a plasma formed in situ. Consequently, relatively sensitive components, such as electrostatic chuck 20, do not need to be covered with a dummy wafer or otherwise protected, as may be required with an in situ plasma cleaning process. In one embodiment, this cleaning system is used to dissociate atoms of the etchant gas remotely, which are then supplied to the process chamber 13. In another embodiment, the etchant gas is provided directly to the process chamber 13. In still a further embodiment, multiple process chambers are used, with deposition and etching steps being performed in separate chambers.

System controller 60 controls the operation of system 10. In a preferred embodiment, controller 60 includes a memory 62, such as a hard disk drive, a floppy disk drive (not shown), and a card rack (not shown) coupled to a processor 61. The card rack may contain a single-board computer (SBC) (not shown), analog and digital input/output boards (not shown), interface boards (not shown), and stepper motor controller boards (not shown). The system controller conforms to the Versa Modular European (“VME”) standard, which defines board, card cage, and connector dimensions and types. The VME standard also defines the bus structure as having a 16-bit data bus and 24-bit address bus. System controller 31 operates under the control of a computer program stored on the hard disk drive or through other computer programs, such as programs stored on a removable disk. The computer program dictates, for example, the timing, mixture of gases, RF power levels and other parameters of a particular process. The interface between a user and the system controller is via a monitor, such as a cathode ray tube (“CRT”) 65, and a light pen 66, as depicted in FIG. 1C.

FIG. 1C is an illustration of a portion of an exemplary system user interface used in conjunction with the exemplary CVD processing chamber of FIG. 1A. System controller 60 includes a processor 61 coupled to a computer-readable memory 62. Preferably, memory 62 may be a hard disk drive, but memory 62 may be other kinds of memory, such as ROM, PROM, and others.

System controller 60 operates under the control of a computer program 63 stored in a computer-readable format within memory 62. The computer program dictates the timing, temperatures, gas flows, RF power levels and other parameters of a particular process. The interface between a user and the system controller is via a CRT monitor 65 and a light pen 66, as depicted in FIG. 1C. In a preferred embodiment, two monitors, 65 and 65A, and two light pens, 66 and 66A, are used, one mounted in the clean room wall (65) for the operators and the other behind the wall (65A) for the service technicians. Both monitors simultaneously display the same information, but only one light pen (e.g. 66) is enabled. To select a particular screen or function, the operator touches an area of the display screen and pushes a button (not shown) on the pen. The touched area confirms being selected by the light pen by changing its color or displaying a new menu, for example.

The computer program code can be written in any conventional computer-readable programming language such as 68000 assembly language, C, C++, or Pascal. Suitable program code is entered into a single file, or multiple files, using a conventional text editor and is stored or embodied in a computer-usable medium, such as a memory system of the computer. If the entered code text is in a high level language, the code is compiled, and the resultant compiler code is then linked with an object code of precompiled windows library routines. To execute the linked compiled object code, the system user invokes the object code causing the computer system to load the code in memory. The CPU reads the code from memory and executes the code to perform the tasks identified in the program.

FIG. 1D shows an illustrative block diagram of the hierarchical control structure of computer program 100. A user enters a process set number and process chamber number into a process selector subroutine 110 in response to menus or screens displayed on the CRT monitor by using the light pen interface. The process sets are predetermined sets of process parameters necessary to carry out specified processes, and are identified by predefined set numbers. Process selector subroutine 110 identifies (i) the desired process chamber in a multichamber system, and (ii) the desired set of process parameters needed to operate the process chamber for performing the desired process. The process parameters for performing a specific process relate to conditions such as process gas composition and flow rates, temperature, pressure, plasma conditions such as RF power levels, and chamber dome temperature, and are provided to the user in the form of a recipe. The parameters specified by the recipe are entered utilizing the light pen/CRT monitor interface.

The signals for monitoring the process are provided by the analog and digital input boards of system controller 60, and the signals for controlling the process are output on the analog and digital output boards of system controller 60.

A process sequencer subroutine 120 comprises program code for accepting the identified process chamber and set of process parameters from the process selector subroutine 110 and for controlling operation of the various process chambers. Multiple users can enter process set numbers and process chamber numbers, or a single user can enter multiple process set numbers and process chamber numbers; sequencer subroutine 120 schedules the selected processes in the desired sequence. Preferably, sequencer subroutine 120 includes a program code to perform the steps of (i) monitoring the operation of the process chambers to determine if the chambers are being used, (ii) determining what processes are being carried out in the chambers being used, and (iii) executing the desired process based on availability of a process chamber and type of process to be carried out. Conventional methods of monitoring the process chambers can be used, such as polling. When scheduling which process is to be executed, sequencer subroutine 120 can be designed to take into consideration the “age” of each particular user-entered request, or the present condition of the process chamber being used in comparison with the desired process conditions for a selected process, or any other relevant factor a system programmer desires to include for determining scheduling priorities.

After sequencer subroutine 120 determines which process chamber and process set combination is going to be executed next, sequencer subroutine 120 initiates execution of the process set by passing the particular process set parameters to a chamber manager subroutine 130A-C, which controls multiple processing tasks in chamber 13 and possibly other chambers (not shown) according to the process set sent by sequencer subroutine 120.

Examples of chamber component subroutines are substrate positioning subroutine 140, process gas control subroutine 150, pressure control subroutine 160, and plasma control subroutine 170. Those having ordinary skill in the art will recognize that other chamber control subroutines can be included depending on what processes are selected to be performed in chamber 13. In operation, chamber manager subroutine 130A selectively schedules or calls the process component subroutines in accordance with the particular process set being executed. Chamber manager subroutine 130A schedules process component subroutines in the same manner that sequencer subroutine 120 schedules the process chamber and process set to execute. Typically, chamber manager subroutine 130A includes steps of monitoring the various chamber components, determining which components need to be operated based on the process parameters for the process set to be executed, and causing execution of a chamber component subroutine responsive to the monitoring and determining steps.

Operation of particular chamber component subroutines will now be described with reference to FIGS. 1A and 1D. Substrate positioning subroutine 140 comprises program code for controlling chamber components that are used to load a substrate onto substrate support number 18. Substrate positioning subroutine 140 may also control transfer of a substrate into chamber 13 from, e.g., a plasma-enhanced CVD (“PECVD”) reactor or other reactor in the multi-chamber system, after other processing has been completed.

Process gas control subroutine 150 has program code for controlling process gas composition and flow rates. Subroutine 150 controls the open/close position of the safety shut-off valves and also ramps up/ramps down the mass flow controllers to obtain the desired gas flow rates. All chamber component subroutines, including process gas control subroutine 150, are invoked by chamber manager subroutine 130A. Subroutine 150 receives process parameters from chamber manager subroutine 130A related to the desired gas flow rates.

Typically, process gas control subroutine 150 opens the gas supply lines, and repeatedly (i) reads the necessary mass flow controllers, (ii) compares the readings to the desired flow rates received from chamber manager subroutine 130A, and (iii) adjusts the flow rates of the gas supply lines as necessary. Furthermore, process gas control subroutine 150 may include steps for monitoring the gas flow rates for unsafe rates and for activating the safety shut-off valves when an unsafe condition is detected.

In some processes, an inert gas, such as argon, is flowed into chamber 13 to stabilize the pressure in the chamber before reactive process gases are introduced. For these processes, the process gas control subroutine 150 is programmed to include steps for flowing the inert gas into chamber 13 for an amount of time necessary to stabilize the pressure in the chamber. The steps described above may then be carried out.

Additionally, when a process gas is to be vaporized from a liquid precursor, for example, tetraethylorthosilane (TEOS), the process gas control subroutine 150 may include steps for bubbling a delivery gas such as helium through the liquid precursor in a bubbler assembly or for introducing the helium to a liquid injection valve. For this type of process, the process gas control subroutine 150 regulates the flow of the delivery gas, the pressure in the bubbler, and the bubbler temperature to obtain the desired process gas flow rates. As discussed above, the desired process gas flow rates are transferred to process gas control subroutine 150 as process parameters.

Furthermore, the process gas control subroutine 150 includes steps for obtaining the necessary delivery gas flow rate, bubbler pressure, and bubbler temperature for the desired process gas flow rate by accessing a stored table containing the necessary values for a given process gas flow rate. Once the necessary values are obtained, the delivery gas flow rate, bubbler pressure and bubbler temperature are monitored, compared to the necessary values and adjusted accordingly.

The process gas control subroutine 150 may also control the flow of heat-transfer gas, such as helium (He), through the inner and outer passages in the wafer chuck with an independent helium control (IHC) subroutine (not shown). The gas flow thermally couples the substrate to the chuck. In a typical process, the wafer is heated by the plasma and the chemical reactions that form the layer, and the He cools the substrate through the chuck, which may be water-cooled. This keeps the substrate below a temperature that may damage preexisting features on the substrate.

Pressure control subroutine 160 includes program code for controlling the pressure in chamber 13 by regulating the size of the opening of throttle valve 26 in the exhaust portion of the chamber. There are at least two basic methods of controlling the chamber with the throttle valve. The first method relies on characterizing the chamber pressure as it relates to, among other things, the total process gas flow, the size of the process chamber, and the pumping capacity. The first method sets throttle valve 26 to a fixed position. Setting throttle valve 26 to a fixed position may eventually result in a steady-state pressure.

Alternatively, the chamber pressure may be measured, with a manometer for example, and the position of throttle valve 26 may be adjusted according to pressure control subroutine 360, assuming the control point is within the boundaries set by gas flows and exhaust capacity. The former method may result in quicker chamber pressure changes, as the measurements, comparisons, and calculations associated with the latter method are not invoked. The former method may be desirable where precise control of the chamber pressure is not required, whereas the latter method may be desirable where an accurate, repeatable, and stable pressure is desired, such as during the deposition of a layer.

When pressure control subroutine 160 is invoked, the desired, or target, pressure level is received as a parameter from chamber manager subroutine 130A. Pressure control subroutine 160 measures the pressure in chamber 13 by reading one or more conventional pressure manometers connected to the chamber; compares the measured value(s) to the target pressure; obtains proportional, integral, and differential (PID) values from a stored pressure table corresponding to the target pressure, and adjusts throttle valve 26 according to the PID values obtained from the pressure table. Alternatively, pressure control subroutine 160 may open or close throttle valve 26 to a particular opening size to regulate the pressure in chamber 13 to a desired pressure or pressure range.

Plasma control subroutine 170 comprises program code for controlling the frequency and power output setting of RF generators 31A and 31B and for tuning matching networks 32A and 32B. Plasma control subroutine 370, like the previously described chamber component subroutines, is invoked by chamber manager subroutine 330A.

An example of a system that may incorporate some or all of the subsystems and routines described above would be the ULTIMA™ system, manufactured by APPLIED MATERIALS, INC., of Santa Clara, Calif., configured to practice the present invention. Further details of such a system are disclosed in the copending, commonly assigned U.S. patent application Ser. No. 08/679,927, filed Jul. 15, 1996, entitled “Symmetric Tunable Inductively-Coupled HDP-CVD Reactor,” having Fred C. Redeker, Farhad Moghadam, Hirogi Hanawa, Tetsuya Ishikawa, Dan Maydan, Shijian Li, Brian Lue, Robert Steger, Yaxin Wang, Manus Wong and Ashok Sinha listed as co-inventors, the disclosure of which is incorporated herein by reference. The described system is for exemplary purpose only. It would be a matter of routine skill for a person of skill in the art to select an appropriate conventional substrate processing system and computer control system to implement the present invention.

### III. Magnetic Shielding

In response to recent trends towards the use of larger semiconductor wafers, the inventors were tasked with developing deposition processes for chambers to accommodate 300-mm wafers. During this development for plasma-based processes, the inventors were faced with unexpectedly large film uniformity problems. Such problems were encountered independent of the material being deposited and were observed, for example, when depositing undoped silicate glass (USG) or fluorinate silicate glass (FSG).

Over a period of time, various approaches that had been successful in improving the process uniformity for 200-mm wafers were attempted, including adjusting the deposition parameters and bias characteristics of the process. While various of these approaches had some effect, they generally affected the process uniformity only to the degree expected from previous experience with 200-mm wafers and were unable to correct the anomalous nonuniformity seen with 300-mm wafers. After excluding these various approaches, the inventors hypothesized that the presence of a spurious magnetic field might be adversely affecting the process characteristics. They therefore sought to confirm this hypothesis by removing magnetic sources from the vicinity of the process 300-mm process chamber, such magnetic sources generally having a field strength greater than about 0.5 gauss, which is of the order of the geomagnetic field. Even after carefully excluding magnetic sources potentially having producing fields greater than about 0.5 gauss, however, the anomalous nonuniformity nevertheless persisted.

After further effort, the inventors therefore theorized that the anomaly might arise from a magnetic source having a field strength less than about 0.5 gauss. For the reasons expressed below on the basis of processing smaller wafers, such field strengths were believed to be sufficiently small not to have a significant effect on process characteristics. It was further hypothesized that the anomaly might result from an ambient magnetic field that could not be excluded by removing specific field sources from the area of the 300-mm process chamber. In order to test these theories, magnetic shielding was use to isolate the process chamber 13 even from an ambient magnetic field and produced a substantial improvement, sufficient to account for the anomalous nonuniformity. The use of magnetic shielding on plasma deposition chambers had previously been restricted to reducing the effect of purely local magnetic fields produced by known permanent magnets having field strengths greater than about 0.5 gauss in the vicinity of the process chamber 13. The inventors' discovery is that, even in the absence of locally induced magnetic fields with such strengths, process uniformity is improved by configuring a high-magnetic-permeability shield around a nonmagnetic process chamber. This suggests that the spurious nonuniformity is manifested with 300-mm wafers for smaller fields than was the case for smaller-diameter wafers. These field strengths may be caused by permanent magnets in the vicinity of the chamber or by the earth itself.

There are several subsequently developed experimental and theoretical considerations that support this hypothesis. During a plasma deposition process, sputter nonuniformity during the deposition of a layer on a substrate arises from impacts by electrons in the plasma. The cyclotron radius for an electron moving in a magnetic field with strength B is given by r_{cyc}=mv/eB, where m and e are the electron mass and charge, and v is the electron's velocity. Under normal deposition conditions for the plasma chamber 13 described above, the plasma species includes a mixture of electrons and ionic particles, each of which has an energy distribution. Electrons with a mean expected kinetic energy on the order of 5 eV thus have a cyclotron radius on the order of 100 mm when the field strength is on the order of 0.5 gauss.

It is thus evident that while the effect on process uniformity of fields having a strength on the order of 0.5 gauss or less should be small for wafers with a diameter less than this cyclotron radius (i.e. for d_{wafer}ˆ100 mm), the effect is increased for wafers with larger diameters. It is believed this is why the process exhibited significant nonuniformity for 300-mm wafers, but was not previously recognized for the smaller 100-mm and 200-mm wafers. The ionic particles in the plasma have a much larger mass than the electrons, and their cyclotron radius is therefore expected to be thousands of times larger. As a result, they have little effect on the sputter uniformity. While the above description of the sputter nonuniformity mechanism has focused on high-density plasma deposition, for which “high density” is understood to refer to a plasma with an ion density exceeding 10¹¹ ions/cm³, the result that the sputter nonuniformity mechanism is dominated by electron activity is generally applicable to any plasma deposition process.

This mechanism has been confirmed qualitatively with experiments in which a small magnetization was deliberately introduced to the plasma. The introduction of a magnetization that corresponds to what would result from field strengths on the order of 0.5 gauss was observed to produce noticeable effects on sputtering uniformity when depositing layers on 300-mm wafers in an HDP-CVD process chamber. With careful observation, the effect could also be seen when depositing layers on 200-mm wafers, but was significantly smaller. It is thus apparent that the influence of magnetic fields less than about 0.5 gauss should be addressed in order to maintain desired process uniformity characteristics as wafer sizes are increased above 200 mm. In terms of the sputter mechanism described above, attenuation of such small fields results in an increase in the cyclotron radius of the plasma electrons. When the mean electron cyclotron radius approximately exceeds the wafer diameter, the sputter nonuniformity decreases.

In one embodiment of the invention, attenuation of fields less than 0.5 gauss within the process chamber 13 is achieved by shielding the nonmagnetic process chamber 13 with high-magnetic-permeability μ sheet metal. The magnetic permeability of a metal is understood to refer to the ratio of magnetic flux induced in the metal to the strength of the magnetic field that induces that flux. Accordingly, a shield's high permeability ensures that magnetic flux will be concentrated in the shield rather than within the nonmagnetic process chamber 13, thereby achieving the desired attenuation. The shielding enclosure is preferably constructed to surround as much of the process chamber 13 as possible, but outside of any RF and/or ground shields that may be used as part of the substrate processing system 10, so as not to affect the RF fields within the chamber. As discussed below, the most effective shielding is one that encloses as much of the process chamber 13 as possible, but partial shields have also been observed to have a favorable effect on the process uniformity.

When a high-μ material is placed in a magnetic field, the local magnetic flux is diverted to the material, causing the desired reduction in field strength. Because the extent to which flux is diverted is proportional to the permeability of the material, continually greater improvement in shielding results with an increase in the permeability of the shielding material. Materials that have suitably high permeabilities to shield the process chamber 13 from the magnetic fields on the order of 0.5 gauss or less include Mumetal®, Hipernom®, HyMu-80®, and Permalloy®, although any material with an appropriately high permeability may be used. Each of these four commercially available materials is a soft alloy that has a permeability relative to the permeability of free space on the order of 10⁴-10⁶; they comprise approximately 80 at. % Ni and 15 at. % Fe, and are balanced primarily with transition elements such as copper, molybdenum, or chromium, depending on the specific recipe used. For example, Mumetal® consists of 77 at. % Ni, 14 at. % Fe, 5 at. % Cu, and 4 at. % Mo. It has a magnetic permeability between approximately 6.0×10⁴ and 2.4×10⁵, depending on the frequency of the magnetic field in which it is placed. The Carpenter Hymu-80® alloy consists of 80 at. % Ni, 15 at. % Fe, 4.2 at. % Mo, 0.5 at. % Mn, 0.35 at. % Si, and 0.02 at. % C. Permalloy® consists of 78 at. % Ni, 16.6 at. % Fe, 4.8 at. % Mo, and 0.9 at. % Mn.

As will be appreciated by those of skill in the art, such shielding materials are substantially different from ground or RF shields that may also be used within the substrate processing system 10. RF shielding is used to block high-frequency (% c100 kHz) interference fields. Such shields are typically constructed of copper, aluminum, galvanized steel, or conductive rubber, plastic, or paints. The high electrical conductivity of such materials, with small (˜1) permeabilities, makes them suitable for blocking electromagnetic signals at high frequency. Accordingly, by positioning the high-permeability shield outside of RF and/or ground shields, the operation of the substrate processing system 10 is not impeded in any way as a result of field attenuation from external or ambient fields having a strength ≦0.5 gauss.

Experimental observations of 300-mm wafers deposited with layers while high-permeability magnetic shielding is in place confirm directly that the sputter nonuniformity is decreased. Careful observations of deposited 200-mm wafers also reveal a beneficial effect from the shielding, although, as expected, the effect is less significant than for the larger wafers. In constructing the high-permeability shield, it is preferable to use a shielding configuration that affords a complete path for the field lines; otherwise there is the possibility that the field lines will exit the material in a place where they will cause unintended and undesirable interference with the operation of the substrate processing system 10. The shape and configuration of the substrate processing system 10 may impose limitations on the extent to which the process chamber 13 can be enclosed by the magnetic shield, but in order to attenuate the fields less than about 0.5 gauss as much as possible, it is preferable to enclose as much of the process chamber 13 as practicable. Less attenuation of such fields permits more plasma electrons at the low end of their energy distribution to have a sufficiently small cyclotron radius to affect sputter uniformity. Even if the configuration of the substrate processing system 10 prevents complete enclosure of the process chamber 13, however, partial shielding is still observed to have a favorable effect on process uniformity because it limits the portion of the plasma electron energy distribution that can have an effect.

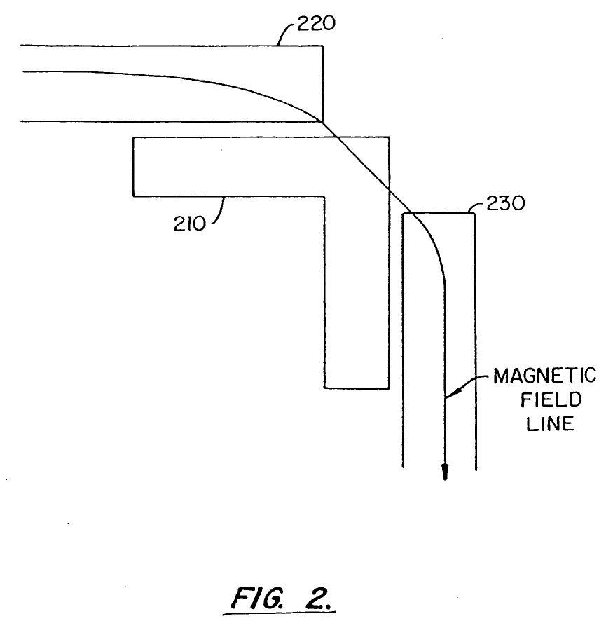

An effective shield that limits the escape of flux can be formed by joining plates of the high-permeability material tightly, minimizing gaps between the plates. One useful configuration is illustrated in FIG. 2. A small angled piece 210 of high-permeability material is positioned to ensure that joined plates 220 and 230 have some overlap. Such positioning helps ensure that the magnetic field lines will not leak to the space enclosed by the shield. The possibility of such undesirable leakage is further decreased by welding the plates 220 and 230 to the angled piece 210.

A number of guidelines may be considered for designing magnetic shielding in accordance with embodiments of the present invention, for improving attenuation of any external source of magnetic field from the plasma processing reactor. One factor which may determine the effectiveness of magnetic shielding is permeability of the shielding material.

As described above, permeability of a material to magnetic fields is referred by Greek symbol μ (Mu). Permeability or μ refers to the ability of a particular material to attract and conduct magnetic field lines (flux). The higher the permeability, the more conductive the material to the magnetic field.

Utilizing a material having a higher permeability for a reactor cover/shield, allows lines of an external magnetic field to concentrate in the reactor cover/shield rather than inside the chamber, where they could adversely affect uniformity of the plasma present therein and hence uniformity of the plasma-based processing. For experimental purposes, a magnetic shielding in the form of a sheet of metal exhibiting a permeability of 400,000 was used. However, embodiments of shielding in accordance with the present invention are not limited to any specific material having a particular permeability value.

Another factor which may determine the effectiveness of magnetic shielding in accordance with embodiments of the present invention is the thickness of the shielding material. Specifically, increased thickness in the shielding material correlates with an increase in the ability of the shielding material to attenuate strength of an external magnetic field, according to Equation (I):
A=μd/D+1; (I)
where:
A=magnetic filed strength attenuation;
μ=permeability of the shielding material;
d=shielding material thickness; and
D=shielding material diameter.

According to Equation (I), in order to decrease the effect of the external magnetic field upon a plasma-based processing chamber, an increased thickness of the high μ shielding material enhances process uniformity. For experimental purposes, magnetic shielding in the form of a sheet having a thickness of 0.040″ was used. However, embodiments of shielding in accordance with the present invention are not limited to any specific material having a particular thickness.

Another factor which may determine the effectiveness of magnetic shielding in accordance with embodiments of the present invention is overlap between individual sections of the magnetic shield enclosing the reactor. Ideally, a cylindrical magnetic shield with infinite length is the best configuration to isolate a point located at the center of this cylinder from any external magnetic source.

In practice, most plasma-based processing chambers can not be shielded from one single infinitely long cylinder. Hence, most plasma-based reactors can be effectively shielded from any external magnetic source by covering each side of the reactor with one or more sections of plates or covers or patches overlapping with each other and forming a continuous path for propagation of the magnetic field lines.

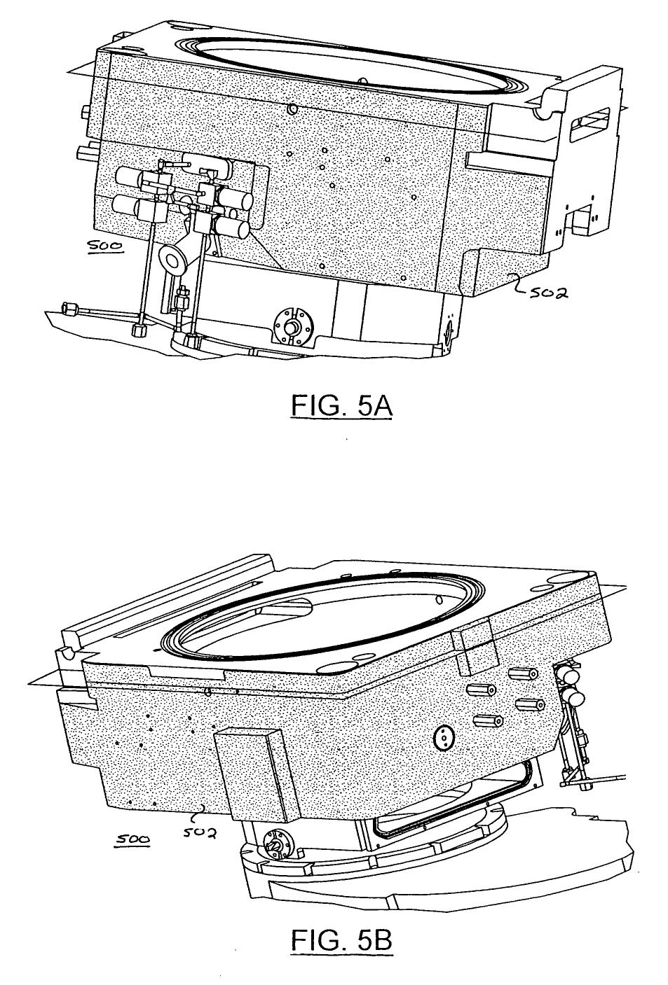

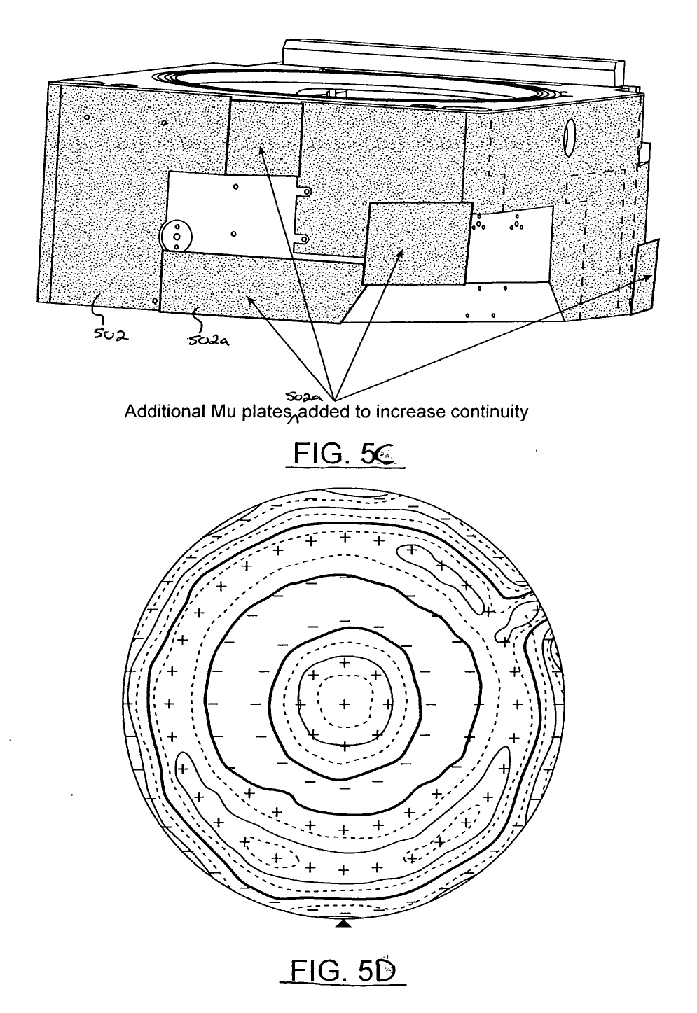

For experimental purposes, a magnetic shield in accordance with an embodiment of the present invention was designed for a HDP-CVD reactor having five different plates/covers/patches enclosing the reactor from all sides and covering as much area as possible to isolate the center of the wafer and the plasma from the source of the external magnetic field. In this particular embodiment (shown in the perspective views of FIGS. 5A-C), an overlap of 0.2″ or more between adjacent sections ensured a continuous presence in the shield in the path of the external magnetic field.

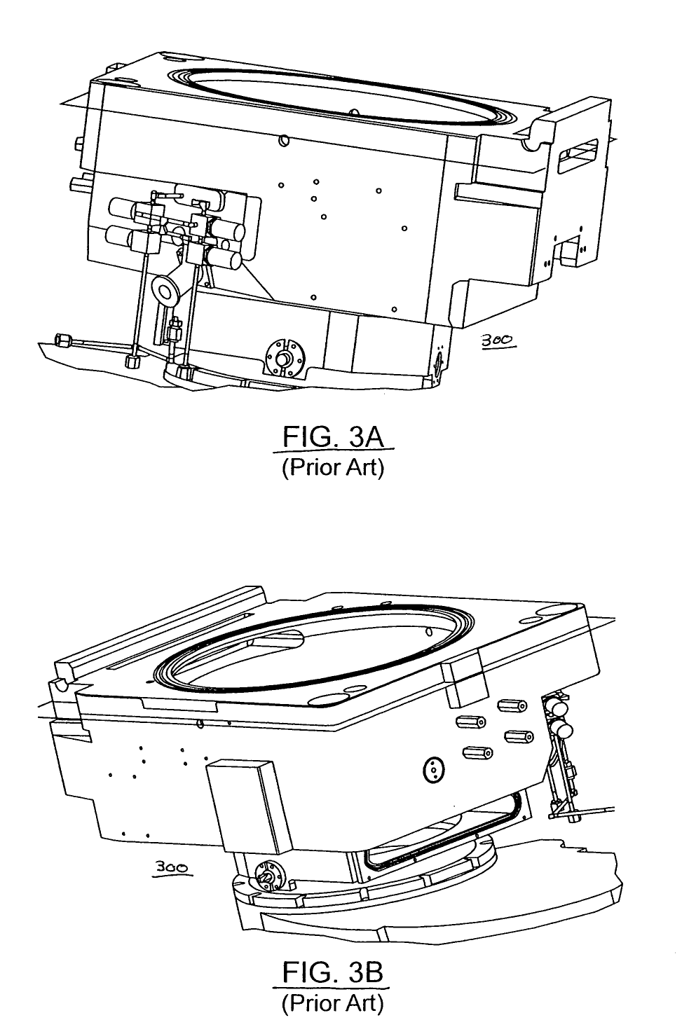

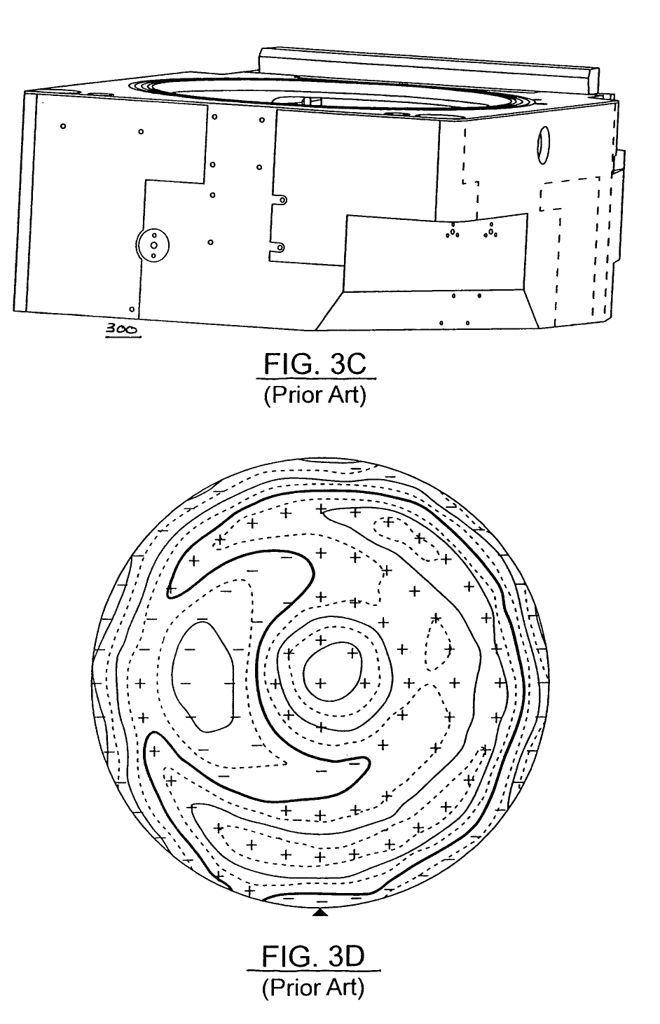

The effect upon uniformity of plasma-based processing by enhanced continuity in coverage of a processing chamber by high-μ shielding, is now discussed in connection with FIGS. 3A-5B.

FIGS. 3A-C show different simplified perspective views of a conventional HDP-CVD chamber 300 lacking any μ-shielding. FIG. 3D shows a contour map of a 300 mm wafer bearing a layer of silicon oxide deposited in the conventional chamber of FIGS. 3A-C. The contour map of FIG. 3D shows substantial nonuniformity of the oxide layer deposited in center left-hand regions of the wafer.

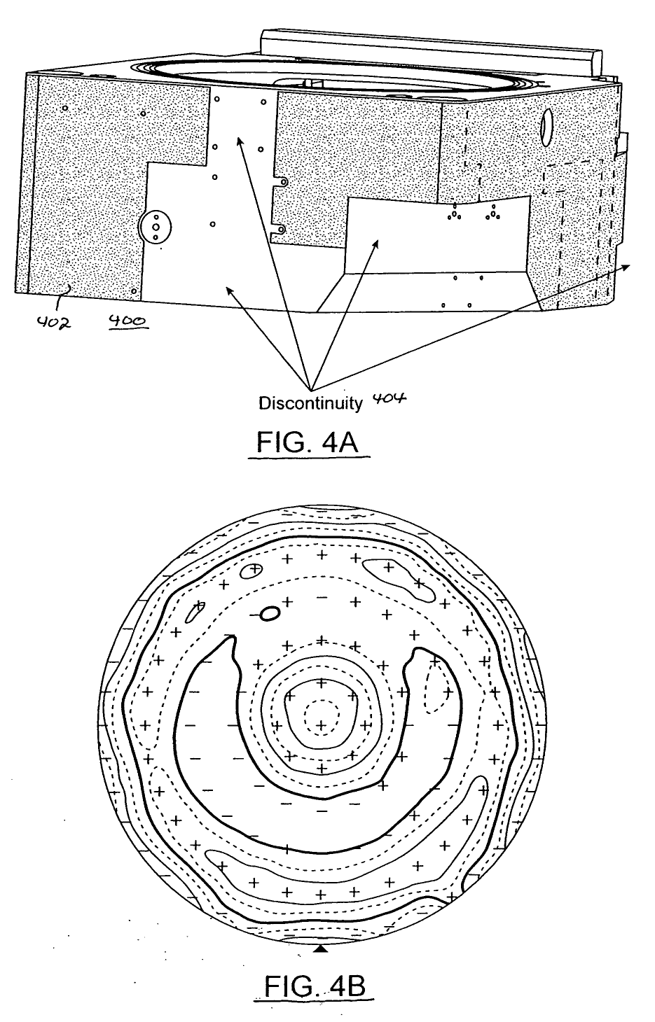

FIG. 4A shows a simplified perspective view of an embodiment of an HDP-CVD chamber 400 bearing μ-shielding 402 which is not continuous and which exposes unshielded regions 404. FIG. 4B shows a contour map of a 300 mm wafer bearing a layer of silicon oxide deposited in the chamber of FIG. 4A. FIG. 4B shows substantial nonuniformity of the oxide layer deposited in center upper wafer regions.

FIGS. 5A-C show simplified perspective views of an embodiment of an HDP-CVD chamber 500 bearing μ-shielding 502 composed of the same material and having the same thickness of the μ-shield of FIG. 4A, but further including additional plates 502a and therefore offering a more continuous profile than the μ-shield of FIG. 4A.

FIG. 5D shows a contour map of a 300 mm wafer bearing a layer of silicon oxide deposited in the chamber of FIGS. 5A-C. FIG. 5D shows substantial improvement in uniformity of the deposited oxide layer.

The following TABLE 1 summarizes characteristics of the film deposited under different shielding conditions.

TABLE 1

| | μ SHIELDING | | |
|---|---|---|---|
| | | | Lid Shield |
| | Lid Shield | Lid Shield and | and Improved |
| STATISTIC | Only | Chamber Shield | Chamber Shield |
| Chamber Shield | FIG. 3A-C | | |
| Contour Map | | | |
| Mean (Å) | 6939 | 7034 | 6942 |
| Std. D (Å) | 173.0 | 162.8 | 154.0 |
| % Std. D (%) | 2.49 | 2.31 | 2.22 |
| Max. (Å) | 7291 | 7448 | 7234 |
| Min. (Å) | 6619 | 6714 | 6557 |
| Range (Å) | 672 | 734 | 577 |
| Interval (Å) | 69.4 | 70.3 | 69.4 |

edge exclusion = 3 mm
# of points sampled = 121

The uniformity of materials formed by plasma-based fabrication processes may generally be expressed as a value known as the “axi-symmetry index”. FIG. 7 shows a simplified schematic view illustrating definition of the axi-symmetry index.

Specifically, the axi-symmetry index may be defined using a mathematical operation of data sampled from thickness measurement of a wafer at multiple points. Specifically, the axi-symmetry index represents the average of absolute values of the thickness difference for all sets (i,j) present within the first four circles 700a-d, with point j diametrically opposite from point i on the wafer 702 (the fifth circle 700e of FIG. 7 represents the edge exclusion). The axi-symmetry index value is thus expressed in units of thickness.

As discussed in detail below, axi-symmetry index values may be utilized to characterize the effects of enhanced μ-shielding upon clustered plasma-based processing chambers.

### V. Cluster Tool

In order to increase throughput in mass-production facilities for fabricating semiconductor devices, it is increasingly common to group together chambers for performing plasma-based processing in the same tool. Chambers clustered together in this manner can be devoted to performing the same type of plasma-based processing (i.e. deposition) or different types of plasma-based processing (i.e. deposition and etching).

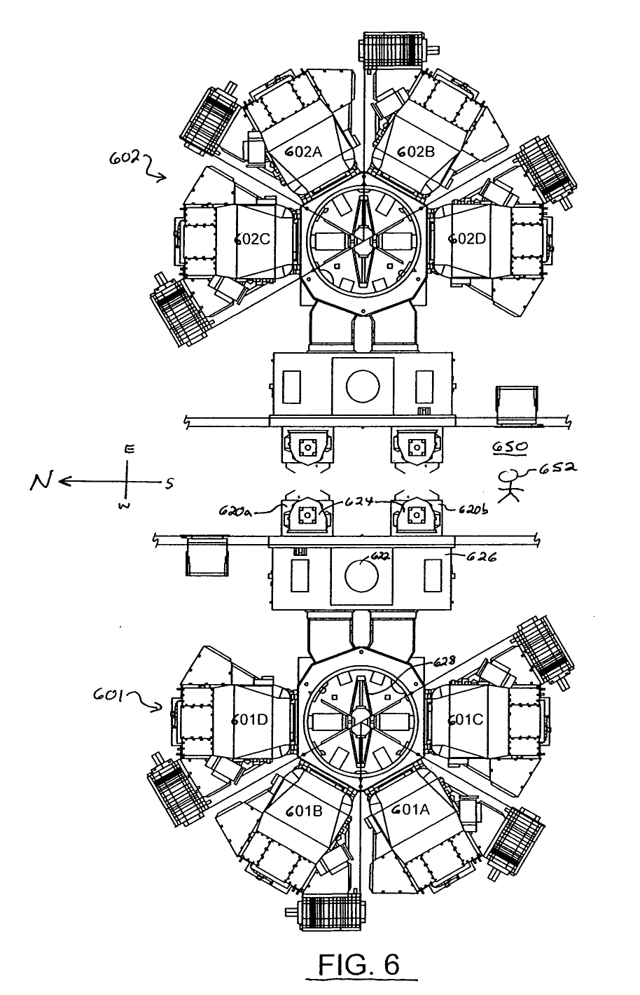

FIG. 6 shows a simplified plan view of one configuration of a pair of plasma-based cluster tools, oriented as indicated with regard to the earth's magnetic field. Cluster tools 601 and 602 are positioned facing one another across a common hallway 650 accessible to facility personnel 652. First cluster tool 601 comprises mechanical interfaces 620a-b configured to receive wafers 622 housed in cassettes 624. Mechanical interfaces 620a-b are in communication with load lock portion 626, which in turn is in communication with transfer robot 628.

Robot 628 is configured to rotate and extend in order to transfer wafers to and from the load lock 626 and the various processing chambers 601A-D. In the embodiment shown in FIG. 6, each chamber 601A-D of tool 601 is configured to perform an HDP-CVD process.

Apart from its different orientation relative to the earth's magnetic field, second cluster tool 602 of FIG. 6 is otherwise identical to first cluster tool 601. Each of chambers 602A-D of tool 602 of FIG. 6 is configured to perform an HDP-CVD process.

The close proximity of the plasma-based chambers of the tool of FIG. 6 can result in their magnetic fields adversely affecting processing uniformity. Specifically, since the vector of the external magnetic field is different for each of the chambers, the magnetic field will influence the plasma uniformity, and hence the process axi-symmetry to different extent for different chambers.

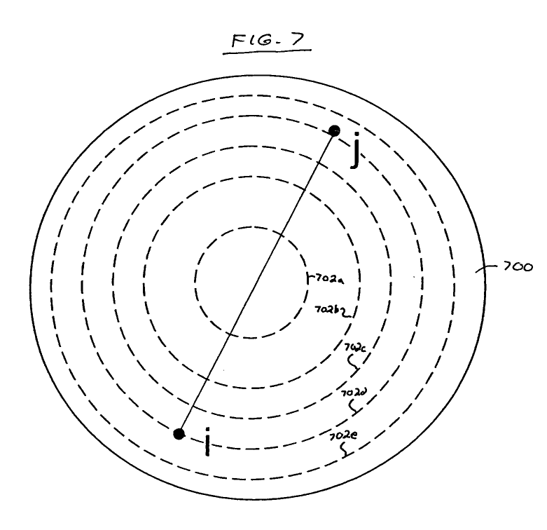

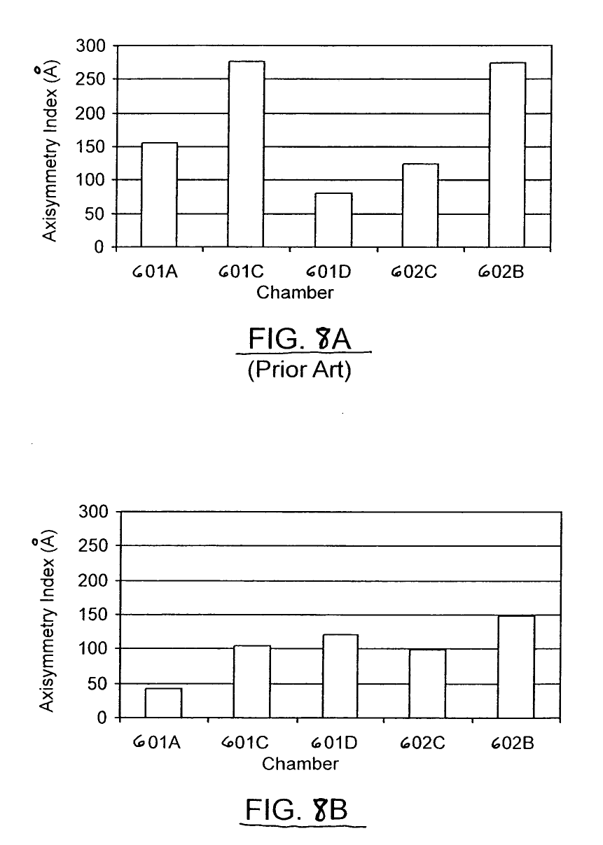

FIG. 8A plots axi-symmetry index for wafers bearing HDP-CVD oxide layers, deposited in certain chambers of a pair of conventional cluster tools of the type shown in FIG. 6. The deposition results shown in FIG. 8A are from unshielded chambers of the type shown in FIGS. 3A-C.

By contrast, FIG. 8B plots axi-symmetry index for wafers bearing HDP-CVD oxide layers, deposited in certain chambers of a pair of cluster tools of the type shown in FIG. 6. The deposition results shown in FIG. 8B are from chambers featuring enhanced shielding of the type shown in FIG. 5A. TABLE 2 plots in tabular form the results of FIGS. 8A-B.

TABLE 2

| | | Axisymmetry Index of | Axisymmetry Index of Film |
|---|---|---|---|
| Cluster | Chamber | Film Deposited w/o | Deposited w/Enhanced |
| Tool # | # | μ-Shield (Å) | μ-Shield (Å) |
| 01 | A | 155 | 45 |
| | C | 275 | 105 |
| | D | 75 | 120 |
| 02 | B | 275 | 150 |
| | C | 125 | 100 |

Comparison of the results of FIGS. 8A-B and TABLE 2 reveals that use of enhanced μ-shielding in accordance with embodiments of the present invention substantially improved the uniformity of HDP-CVD processing. For example, while FIG. 8A indicates axi-symmetry index maxima of about 275 Å (chambers 601C and 602B), FIG. 8B indicates axi-symmetry maxima of only about 150 Å (chamber 602B).

Moreover, FIGS. 8A-B also reveal that the use of enhanced shielding substantially reduced chamber-to-chamber variation in uniformity. For example, while FIG. 8A indicates differences in axi-symmetry index of about 80 Å or greater between unshielded chambers clustered on a first tool, FIG. 8B indicates reduced differences in axi-symmetry index of about 80 Å or less for the corresponding chambers featuring the enhanced shielding in accordance with embodiments of the present invention. An even greater improvement in uniformity between different chambers clustered on a second tool is revealed by comparing the results of FIGS. 8A-B.

U.S. Pat. No. 6,447,651 (“the 651 patent”) is incorporated by reference herein for all purposes. Like the instant application, the '651 patent describes the use of magnetic shielding to improve uniformity of plasma processing. In particular, the '651 patent emphasizes the effect upon film thickness uniformity, of the sputtering process concurrent with deposition during HDP-CVD.

Unlike the '651 patent, however, improved thickness uniformity according to embodiments of the present invention cannot be attributed solely to such sputtering processes.

Specifically, uniformity data of FIGS. 8A-B reflects HDP-CVD of an oxide film having a thickness of around 5000 Å. During such an HDP-CVD process, about 10% of oxide material originally formed by deposition is typically removed by the concurrent sputtering process. Therefore, the thickness of material sputtered in FIGS. 8A-B would be about 500 Å.

The concurrent sputtering of the HDP-CVD process typically exhibits a sensitivity of to variation in electromagnetic field of about 10%. Accordingly, for the HDP-CVD process shown in FIGS. 8A-B, variation in sputter uniformity could account for a difference in film thickness of only about 50 Å. This value is smaller than the changes in axisymmetry index of 80 Å observed between the chambers clustered on the same tool as shown in FIGS. 8A-B. Improved magnetic shielding in accordance with embodiments of the present invention thus must be affecting not only the uniformity of the HDP-CVD sputtering process, but also uniformity of the initial, pre-sputtering HDP-CVD deposition process.

While the above description relates to shielding clustered plasma-based processing chambers against magnetic fields generated by adjacent chambers, enhanced magnetic shielding in accordance with embodiments of the present invention can also serve to protect a tool from nonuniformity resulting from other types of external magnetic fields.

For example, HDP-CVD processes typically operate at pressures of between about 2-10 mTorr. At these low pressures, the inertial force on the ions is significantly larger than the viscous force. The relative magnitude of the magnetic force relative to the inertial force can be expressed according to Equation (II):

$$\frac{MagneticForce}{InertialForce} = ( qvB ) / ( {mv}^{2} \text{/} L ) ; where \\ q = ion charge ; \\ v = ion bulk velocity ; \\ B = Lorentz force ; \\ m = ion mass ; and \\ L = chamber length scale . \qquad ( II )$$

Taking the Lorentz force (B) of the earth's geomagnetic field as ˜50e⁻⁶ N/Am, the ion charge (q) as ˜1.6e⁻¹⁹ C, the ion mass (m) as ˜1e⁻¹⁵ kg, the ion bulk velocity (v) as ˜10 m/sec, and the chamber length scale (L) as ˜0.1 m, under typical HDP-CVD processing conditions the magnetic force is seen to be approximately an order of magnitude less than the inertial force. This difference is sufficiently large to alter the momentum of ions in the processing plasma, introducing nonuniform processing.

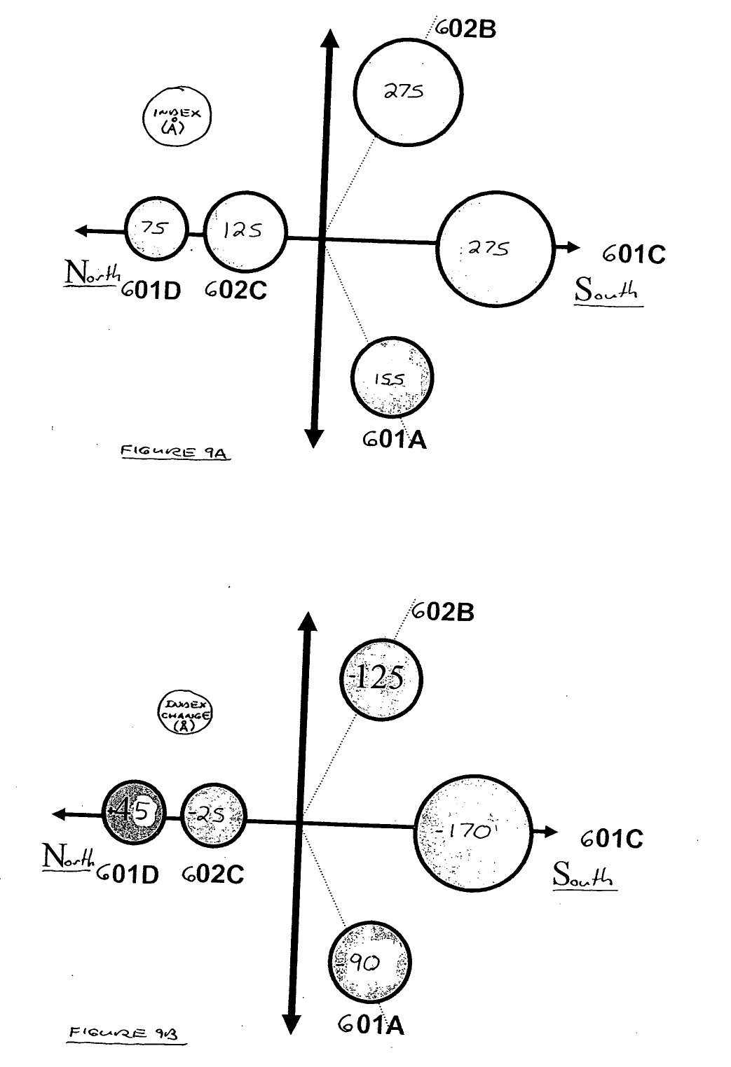

FIG. 9A is a schematic diagram correlating the axi-symmetry index data of FIG. 8A with orientation of clustered plasma-based processing chambers relative to the earth's magnetic field. FIG. 9B is a schematic diagram correlating the change in axi-symmetry index data between FIGS. 8A-B, with orientation of clustered plasma-based processing chambers relative to the earth's magnetic field.

Review of FIGS. 9A-B reveals that the differently-oriented plasma-based chambers exhibit different processing uniformity. Taken together with the analysis presented above in conjunction with Equation (II), these differences may indicate the impact of magnetic fields even as small as geo-magnetic field, upon uniformity of a plasma-based process working at low pressure (˜mTorr pressure scale).

While the above is a complete description of specific embodiments of the present invention, various modifications, variations, and alternatives may be employed. For example, those of ordinary skill in the art will realize that the material used to shield the process chamber may have different compositions and may be configured differently without departing from the spirit of the invention.

And while the above description relates to shielding a HDP-CVD chamber from the effects of external magnetic fields, embodiments in accordance with the present invention are not limited to this form of plasma-based processing. The uniformity of other types of plasma-based processing, including but not limited to PE-CVD, and plasma etching may also be improved by shielding from external magnetic fields in accordance with embodiments of the present invention.

Other variations will also be apparent to persons of skill in the art. These equivalents and alternatives are included within the scope of the present invention. Therefore, the scope of this invention is not limited to the embodiments described, but is defined by the following claims and their full scope of equivalents.

What is claimed is:

1. A method of forming a material by plasma-assisted chemical vapor deposition, the method comprising:
disposing a reactant gas in a first plasma processing chamber of a cluster tool, the first plasma processing chamber featuring a first electromagnetic shield;
disposing the reactant gas in a second plasma processing chamber of the cluster tool, the second plasma processing chamber featuring a second electromagnetic shield; and
introducing high density plasma into the first and second plasma processing chambers to cause reaction between reactants and deposit material therein,
wherein the first and second electromagnetic shields insulate the first and second plasma processing chambers from external electromagnetic fields, such that an axisymmetry index of a film deposited in the first chamber differs from an axisymmetry index of a film deposited in the second chamber by about 80 Å or less.

2. The method of claim 1 wherein the first electromagnetic shield insulates the first chamber from an external electromagnetic field associated with operation of the second chamber, and wherein the second electromagnetic shield insulates the first chamber from an external electromagnetic field associated with operation of the first chamber.

3. The method of claim 1 wherein the electromagnetic shields insulate the first and second plasma processing chambers from external electromagnetic fields associated a different orientation of the first and second plasma processing chambers with respect to the Earth's magnetic field.

4. The method of claim 1 wherein the material comprises silicon oxide.

5. The method of claim 1 wherein the material is deposited by high density chemical vapor deposition (HDP-CVD).

6. The method of claim 5 wherein a presence of the first and second electromagnetic shields improves a uniformity of the material as deposited, prior to concurrent HDP-CVD sputtering.

7. The method of claim 6 wherein the material comprises silicon oxide, and the uniformity is improved to be within one percent or less of the oxide as originally deposited, prior to the concurrent sputtering process.

8. A method of quantifying uniformity of a material deposited on a substantially circular substrate, the method comprising:
sampling a property of the material at a plurality of pairs of diametrically opposed positions on a circumference of a sampling circle having a center coincident with a center of the substrate;
determining a plurality of differences between the property sampled at each of the diametrically opposed position pairs;
taking the absolute value of each of the plurality of the differences; and
averaging the absolute values to calculate an axisymmetry index having a unit that is the same as the sampled property.

9. The method of claim 8 further comprising:
sampling the material property at a plurality of pairs of diametrically opposed positions on a circumference of a second sampling circle also having a center coincident with the substrate center;
determining a plurality of differences between the property sampled at each of the diametrically opposed position pairs on the second sampling circle; and
taking the absolute value of each of the plurality of the differences of the property on the circumference of the second sampling circle;
wherein averaging the absolute values to calculate an axisymmetry index having a unit that is the same as the sampled property, includes averaging the absolute values of each of the plurality of the differences of the property on the circumference of the second sampling circle.

10. The method of claim 9 wherein the substrate radius is 150 mm, wherein averaging the absolute values further comprises including averaging absolute values of each of a plurality of differences of the property sampled at diametrically opposed positions located on the circumference of a third and a fourth sampling circle.

11. The method of claim 8 wherein a thickness of the deposited material is sampled as the property.

12. The method of claim 8 wherein a radius of the sampling circle is less than an edge exclusion radius.

13. A method of forming a material by high density plasma chemical vapor deposition (HDP-CVD), the method comprising:
disposing a reactant gas in a plasma processing chamber equipped with an electromagnetic shield;
introducing high density plasma into the plasma processing chamber to cause reaction between reactants and deposit material therein, wherein a presence of the electromagnetic shield improves a uniformity of the material as deposited, prior to concurrent HDP-CVD sputtering.

14. The method of claim 13 wherein the material comprises silicon oxide, and the uniformity is improved to be within one percent or less of the oxide as originally deposited, prior to the concurrent HDP-CVD sputtering process.

15. The method of claim 13 wherein the chamber is a part of a cluster tool, and the electromagnetic shield insulates the chamber from an external electromagnetic field associated with operation of other chambers of the cluster tool.

16. The method of claim 13 wherein the electromagnetic shield insulates the chamber from the Earth's magnetic field.

17. A semiconductor processing cluster tool comprising:
a first plasma processing chamber equipped with a first electromagnetic shield and configured to receive a process gas; and
a second plasma processing chamber equipped with a second electromagnetic field and configured to receive the process gas, the first and second electromagnetic shields insulating the first and second plasma processing chambers from external electromagnetic fields, such that an axisymmetry index of the material deposited in the first chamber differs from an axisymmetry index of the material deposited in the second chamber by about 80 Å or less.

18. The semiconductor processing cluster tool of claim 17 wherein the first and second electromagnetic shields exhibit a magnetic permeability of greater than 1×10⁴ times the magnetic permeability of free space.

19. The semiconductor processing cluster tool of claim 17 wherein the first and second electromagnetic shields comprise greater than 75 at. % Ni and greater than 12 at. % Fe.

20. The semiconductor processing cluster tool of claim 19 wherein the first and second magnetic shields comprise greater than 4 at. % Mo.
